(19) United States
(12) Patent Application Publication
(10) Pub. No.: US 2025/0308960 A1
(43) Pub. Date: Oct. 2, 2025

(54) APPARATUS AND METHOD FOR DETECTING AND MONITORING OBJECTS IN A FLUID BATH AND ADJUSTING THE FLUID BATH BASED ON THE MEASURED OBJECT PROPERTIES

(71) Applicant: Tokyo Electron Limited, Tokyo (JP)

(72) Inventor: Joel ESTRELLA, Austin, TX (US)

(73) Assignee: Tokyo Electron Limited, Tokyo (JP)

(21) Appl. No.: 18/622,541

(22) Filed: Mar. 29, 2024

(51) Int. Cl. H01L 21/67; G06T 7/70; G06V 10/74; G06V 20/40; H01L 21/66

(52) U.S. Cl. CPC H01L 21/67253; G06T 7/70; G06V 10/761; G06V 20/40; H01L 22/26; G06T 2207/10016; G06T 2207/30148

(57) ABSTRACT

Techniques herein include an apparatus and method for measuring and monitoring properties of objects, such as bubbles, detected in a fluid in a semiconductor processing apparatus. The method can track the detected objects over time through multiple frames of video data and determine metrics for the detected objects to improve tracking accuracy as well as correlate recipe parameters to resulting wafer quality processed via the recipe parameters. Based on the determined correlation between the wafer quality data and the determined object metrics, the recipe parameters can be adjusted to improve wafer quality further.

### FIELD OF THE INVENTION

The present disclosure relates to an apparatus and method of detecting and monitoring objects in a fluid bath and adjusting flow dynamics of the fluid for applications in semiconductor manufacturing processes.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the development of wafers in semiconductor processing, wafer baths can be a step or module included in the manufacturing process. In this step, wafers can be submerged within a fluid in the hardware for processing. During this step, differences in recipes and the hardware can affect processing of the wafers. However, correlating the differences in results to varying parameters of the recipes can be difficult without a fiducial (marker). Thus, objects in the fluid can be leveraged to measure metrics of the fluid, such as bubbles generated and moving within the bath.

The properties of the bubbles in the bath can be affected by many differences, such as changes in the recipe or the bath hardware. Other factors such as the number of bubbles can also be affected by these changes. As such, an apparatus and method for detecting and monitoring objects in the bath, and adjusting processing recipes based on the measured object properties is desired.

### SUMMARY

The present disclosure relates to a semiconductor processing apparatus for detecting objects in a fluid, including processing circuitry configured to receive video data including a plurality of frames, detect, in a first frame of the video data, a first object, determine first metrics for the first object in the first frame, the first metrics including a position of the first object and a size of the first object, detect, in a second frame of the video data, a second object, determine second metrics for the second object in the second frame, the second metrics including a position of the second object and a size of the second object, determine a first difference between the first metrics of the first object in the first frame and the second metrics of the second object in the second frame, and based on the determined first difference, determine whether the first object in the first frame is a same object as the second object in the second frame.

In an embodiment, the processing circuitry is further configured to receive data related to a quality of a wafer processed in the fluid using a corresponding first processing recipe defining a first set of parameters, and based on the wafer quality data, the first metrics, and the second metrics, adjust the first set of parameters of the first recipe to generate a second recipe.

In an embodiment, the processing circuitry determines whether the first object in the first frame is the same object as the second object in the second frame based on the determined first difference by based on the determined first difference, assigning a probability value to the second object in the second frame defining a likelihood of the first object in the first frame being the same object as the second object in the second frame.

In an embodiment, the processing circuitry is configured to determine the first difference by determining a difference between the size of the first object in the first frame and the size of the second object in the second frame.

In an embodiment, the processing circuitry is configured to determine the first difference by determining a distance between the position of the first object in the first frame and the position of the second object in the second frame.

In an embodiment, the processing circuitry is configured to determine the first difference by determining an area overlap between an area of the first object in the first frame and an area of the second object in the second frame.

In an embodiment, the apparatus further comprises a first light source configured to emit light having a predetermined wavelength range; and an imaging device configured to obtain the video data by capturing the emitted light from the first light source, the imaging device being sensitive to the predetermined wavelength range of the emitted light.

In an embodiment, the first light source is configured to emit light along a predetermined plane through a volume of the fluid, and the imaging device is configured to only capture the emitted light by the first light source along the predetermined plane through the volume of the fluid.

In an embodiment, the processing circuitry is configured to detect the first object in the first frame and detect the second object in the second frame by applying, to each pixel in each frame of the video data, a filter to generate a transformed frame, and detecting, in the transformed frames, the first object and the second object.

In an embodiment, the processing circuitry is further configured to after determining the second metrics for the second object in the second frame, determine whether additional objects are disposed in the second frame, upon determining additional objects are disposed in the second frame, detect, in the second frame, a third object, and determine third metrics for the third object in the second frame, the third metrics including a position of the third object and a size of the third object.

In an embodiment, the processing circuitry is further configured to determine a second difference by determining a difference between the first metrics of the first object in the first frame and the third metrics of the third object in the third frame, and the processing circuitry determines whether the first object in the first frame is the same object as the second object in the second frame or the same object as the third object in the second frame based on the determined first difference and the determined second difference.

In an embodiment, the processing circuitry determines whether the first object in the first frame is the same object as the second object in the second frame or the same object as the third object in the second frame based on the determined first difference and the determined second difference by based on the determined first difference, assigning a first probability value to the second object in the second frame defining a likelihood of the first object in the first frame being the same object as the second object in the second frame, based on the determined second difference, assigning a second probability value to the third object in the second frame defining a likelihood of the first object in the first frame being the same object as the third object in the second frame, and determining whether the first object in the first frame is the same object as the second object in the second frame or the same object as the third object in the second frame based on the second object or the third object having the higher probability value.

In an embodiment, the processing circuitry is configured to detect the first object in the first frame by determining a first region of interest in an area of the first frame, the first region of interest including the first object disposed therein, and detecting, in the first region of interest, the first object.

In an embodiment, the processing circuitry is configured to detect the second object in the second frame by determining a second region of interest in an area of the second frame, the second region of interest including the second object disposed therein, the second region of interest having a position and size within the area of the second frame that is the same as a position and size of the first region within the area of the first frame, and detecting, in the second region of interest, the second object.

In an embodiment, the first object and the second object are bubbles.

The present disclosure additionally relates to a method of detecting objects in a fluid in a semiconductor manufacturing apparatus, including receiving video data including a plurality of frames; detecting, in a first frame of the video data, a first object; determining first metrics for the first object in the first frame, the first metrics including a position of the first object and a size of the first object; detecting, in a second frame of the video data, a second object; determining second metrics for the second object in the second frame, the second metrics including a position of the second object and a size of the second object; determining a first difference between the first metrics of the first object in the first frame and the second metrics of the second object in the second frame; and based on the determined first difference, determining whether the first object in the first frame is a same object as the second object in the second frame.

The present disclosure additionally relates to a non-transitory computer-readable storage medium including executable instructions, which when executed by circuitry, cause the circuitry to perform a method of detecting objects in a fluid in a semiconductor manufacturing apparatus, including receiving video data including a plurality of frames; detecting, in a first frame of the video data, a first object; determining first metrics for the first object in the first frame, the first metrics including a position of the first object and a size of the first object; detecting, in a second frame of the video data, a second object; determining second metrics for the second object in the second frame, the second metrics including a position of the second object and a size of the second object; determining a first difference between the first metrics of the first object in the first frame and the second metrics of the second object in the second frame; and based on the determined first difference, determining whether the first object in the first frame is a same object as the second object in the second frame.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1A is a schematic of a bubble detected moving through a fluid, according to an embodiment of the present disclosure.

FIG. 1B is a schematic of a bubble detected moving quickly through a fluid, according to an embodiment of the present disclosure.

FIG. 1C is a schematic of multiple bubbles detected moving through a fluid, according to an embodiment of the present disclosure.

FIG. 2A is a schematic of bubbles detected across frames, according to an embodiment of the present disclosure.

FIG. 2B is a schematic of detecting and tracking a bubble based on size metrics, according to an embodiment of the present disclosure.

FIG. 2C is a schematic of bubbles detected across frames, according to an embodiment of the present disclosure.

FIG. 2D is a schematic of detecting and tracking a bubble based on overlap, according to an embodiment of the present disclosure.

FIG. 2E is a schematic of bubbles detected across frames, according to an embodiment of the present disclosure.

FIG. 2F is a schematic of detecting and tracking a bubble based on distance, according to an embodiment of the present disclosure.

FIG. 3A is a flow chart for a method of monitoring objects in a fluid, according to an embodiment of the present disclosure.

FIG. 3B is a flow chart for a sub-method for detection in a region of interest (ROI), according to an embodiment of the present disclosure.

FIG. 3C is a flow chart for a sub-method of detecting objects in a frame, according to an embodiment in the present disclosure.

FIG. 3D is a flow chart for a sub-method of detecting objects in a frame, according to an embodiment in the present disclosure.

FIG. 3E is a flow chart for a sub-method of detecting objects in a frame, according to an embodiment in the present disclosure.

FIG. 3F is a flow chart for a sub-method of detecting objects in a frame, according to an embodiment in the present disclosure.

FIG. 4 is a flow chart describing a method of adjusting a semiconductor manufacturing process based on tracked bubble metrics, according to an embodiment of the present disclosure.

FIG. 5 is a schematic of a hardware system for performing a method, according to an embodiment of the present disclosure.

FIG. 6 is a schematic of a hardware configuration of a device for performing a method, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Wafer baths can be a step or module included in the semiconductor manufacturing process where each step or module can implement a different recipe for processing the wafer. Video recording of a wafer bath holding a fluid can be used to observe the bath and the bubbles occurring within the bath over time. The video recording, or video data, of the wafer bath hardware can be used to provide information about the wafer bath, such as the observation of bubbles within the bath and movement of the bubbles. This observation can provide insight into what is occurring within the bath and differences such as recipe or hardware changes. The video data can be analyzed and analysis methods can be developed to determine this information and automate the process through time.

Described herein is a method for detecting objects, such as bubbles, in a bath or volume of fluid, determining metrics of the objects, and monitoring the objects for adjusting parameters of the wafer bath recipe, hardware, or other factors affecting the quality of the resultant wafer after processing.

The method can include determining or detecting the bubbles within the video data. This step can determine when and where the bubbles occur. Since much can be occurring within the bath and there can be many bubbles present at any time, careful methods of analysis can be helpful in determining individual bubbles within the bath through time. Once individual bubbles can be determined, additional information, such as size and location, can be determined.

The method for detecting the object (bubbles) within the bath and through time can then be used to determine the movement of bubbles within the bath. The bubbles can, in some instances, not always be at the same location through time and the movement of the bubbles can occur at different rates. Additional analysis methods can then be developed to track individual bubbles within the bath. With the tracking of a target bubble, additional information can be determined, such as the location of the target bubble and the rate of movement or velocity of the bubble through time and at different locations within the bath. Differences of the detection and tracking of these bubbles can also be observed across multiple datasets, which can include different hardware or changes in recipes.

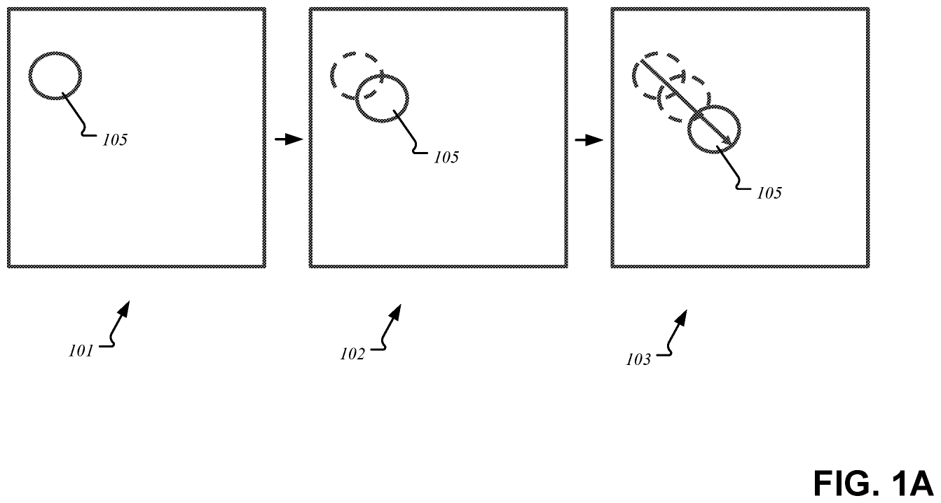

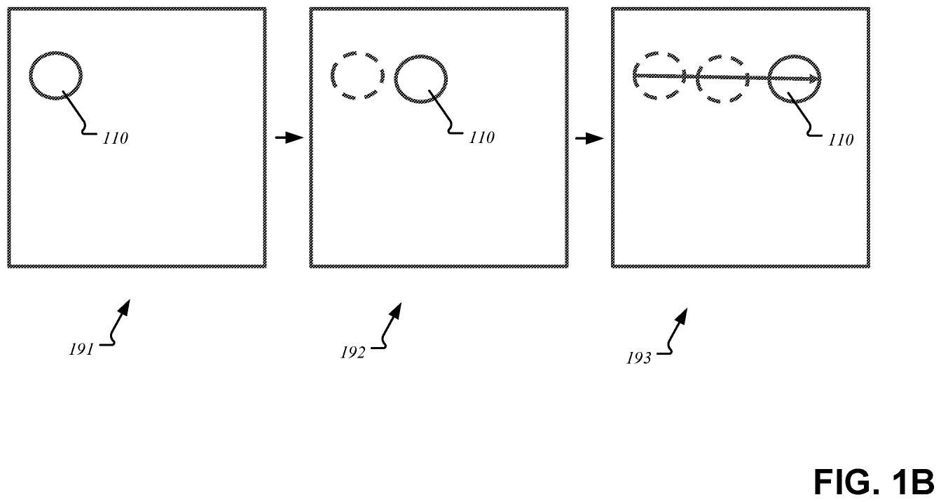

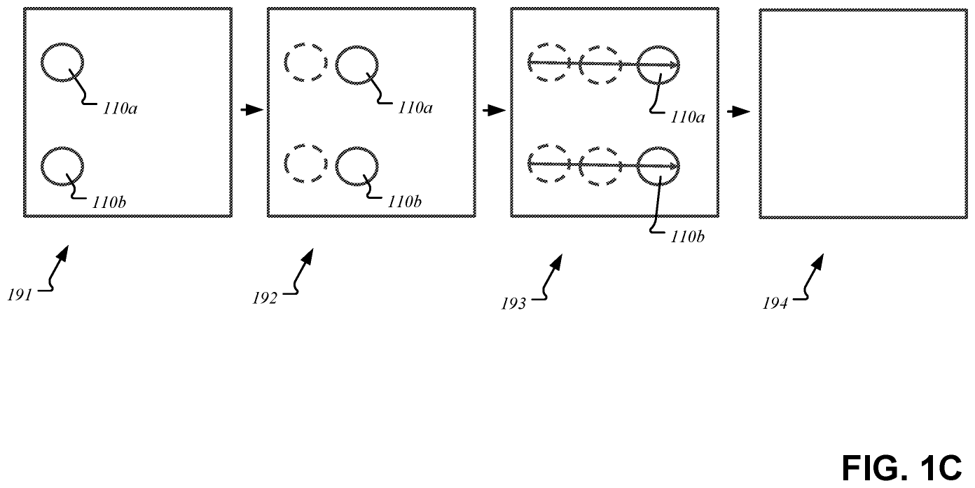

To this end, FIG. 1A is a schematic of a bubble detected moving through a fluid, according to an embodiment of the present disclosure. In an embodiment, video data of the wafer bath fluid can be obtained or captured by an imaging device, and the video data can include frames or single images compiled over a duration of time to form the video data. As shown, for example, a bubble 105 can be imaged in a first frame 101 having a first position, then imaged again in a second frame 102 having a second position, then imaged again in a third frame 103 having a third position. Notably, the previous positions are shown with a dashed outline, and thus the most recent position is shown as the solid outline.

In an embodiment, a movement or translation of the bubble 105 can be small for each frame, and therefore the second position of the bubble 105 in the second frame 102 can overlap the first position of the bubble 105 in the first frame 101. Similarly, as shown, the third position of the bubble 105 in the third frame 103 can overlap the second position of the bubble 105 in the second frame 102. An overall movement is indicated by the arrow. The movement or translation of the bubble 105 can be even smaller where the third position of the bubble 105 in the third frame 103 can overlap the first position of the bubble 105 in the first frame 101. Of course, the movement or translation of the bubble 105 can be large enough where the second position of the bubble 105 in the second frame 102 can have no overlap with the first position of the bubble 105 in the first frame 101.

To this end, FIG. 1B is a schematic of a bubble detected moving quickly through a fluid, according to an embodiment of the present disclosure. In an embodiment, a bubble 110 can be imaged in a first frame 191 having a first position, then imaged again in a second frame 192 having a second position, then imaged again in a third frame 193 having a third position. Again, the previous positions are shown with a dashed outline and the most recent position is shown as the solid outline.

In an embodiment, a movement or translation of the bubble 110 can be large for each frame, and therefore the second position of the bubble 110 in the second frame 192 can have no overlap with the first position of the bubble 110 in the first frame 191, and similarly, the third position of the bubble 110 in the third frame 193 can have no overlap with the second position of the bubble 110 in the second frame 192.

The movement or translation of the bubble 110 (and the bubble 105), as well as other measurable metrics of the bubble 110 (and the bubble 105), can elucidate the behavior of the fluid in the wafer bath and be used to correlate a resulting wafer quality with the fluid behavior due to particular parameters of a processing recipe.

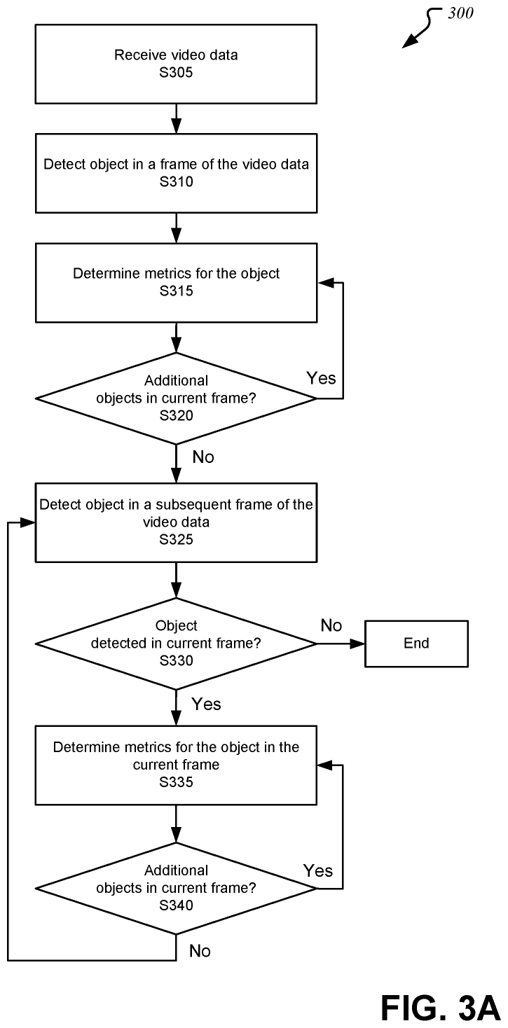

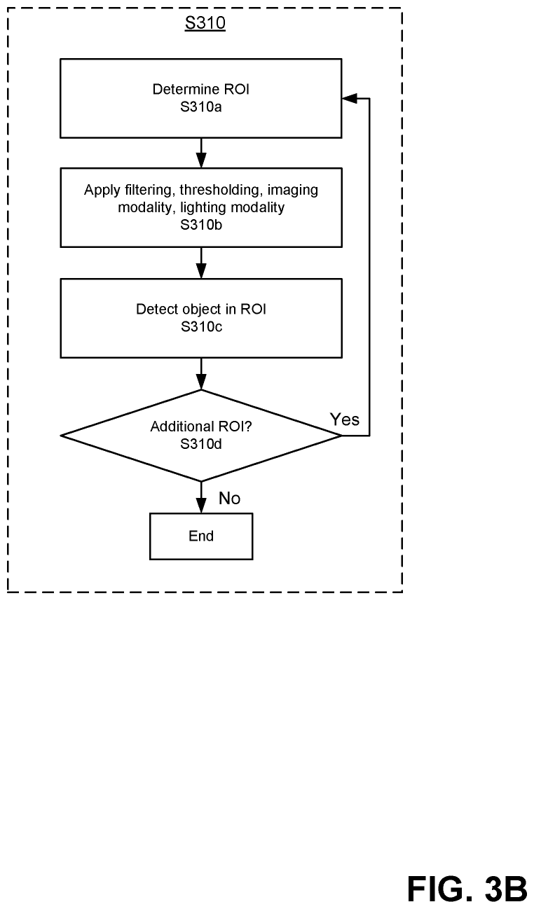

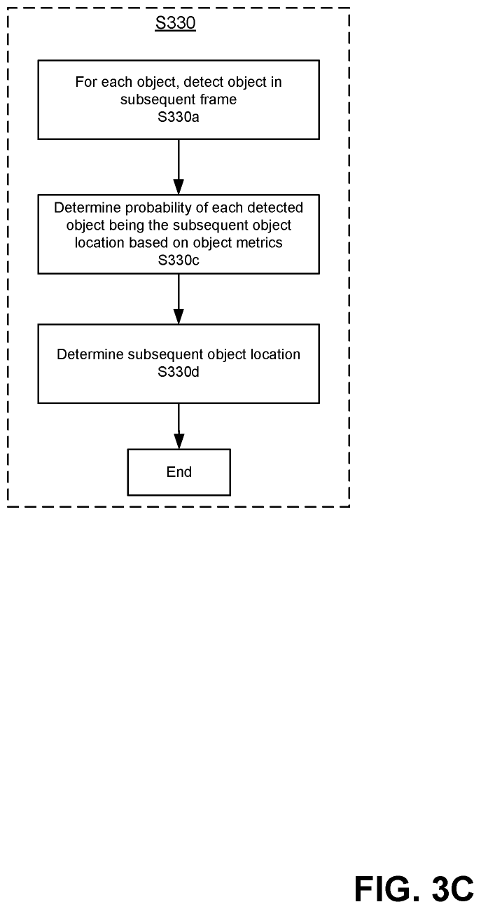

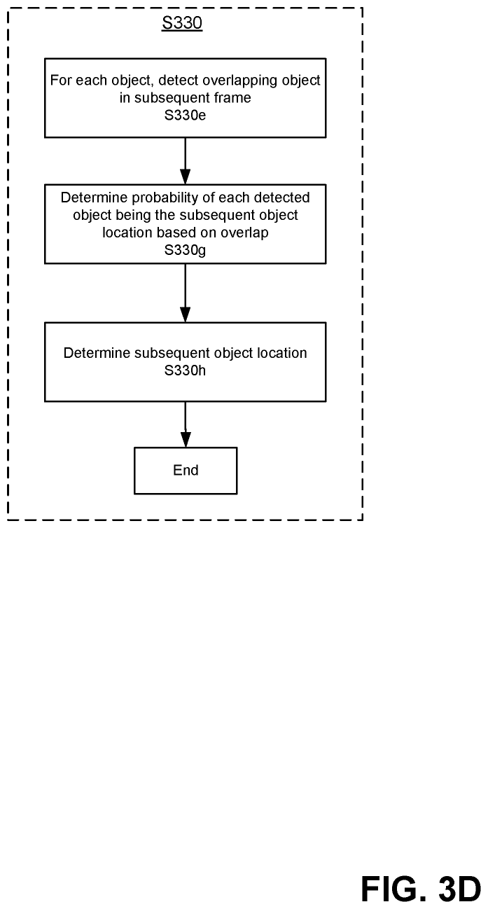

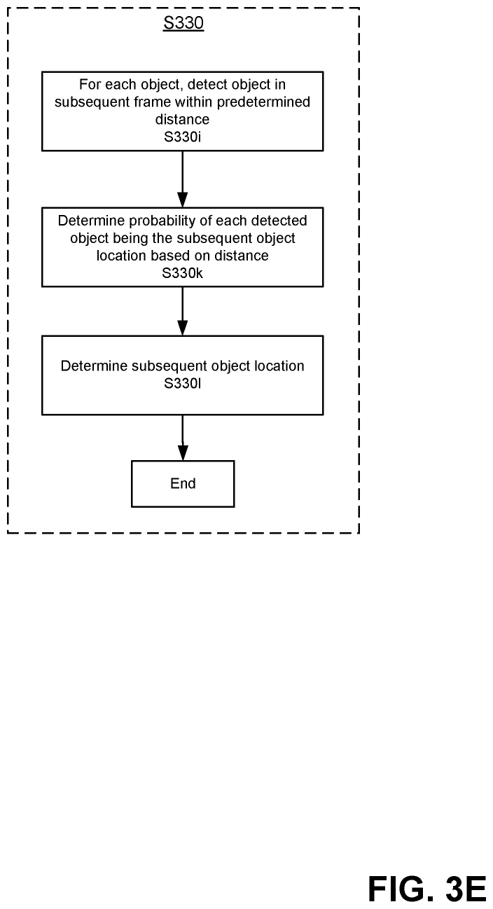

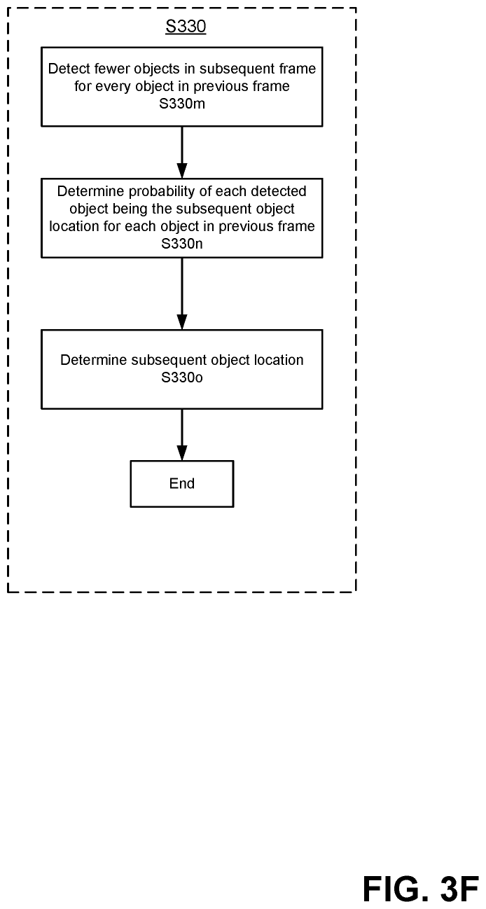

While only one bubble being imaged and detected in the frames of FIGS. 1A and 1B can occur at times, other times more than one of the bubble can be imaged in a single frame. Thus, now with reference to FIG. 3A, a method can be described for detecting the bubbles, determining metrics of the bubbles, detecting the bubbles when the bubbles are imaged in subsequent frames of the video data, and determining updated metrics of the bubbles in the subsequent frames. It may be appreciated that the subsequent frame can be a frame immediately following a reference or original frame, or generally (and temporally) following after the original frame. That is, the subsequent frame need not be frame n+1, where n is the original frame, and can be frame n+2, or n+3, or n+m, where m is an integer.

FIG. 3A is a flow chart for a method 300 of monitoring objects in a fluid, according to an embodiment of the present disclosure. In an embodiment, at step S305, video data can be received. As previously described, the video data can be captured or obtained by an imaging device, such as a camera, and the video data can include a compilation of individual frames or images over time. In an embodiment, the camera can be configured to image in various imaging modalities. For example, the camera can image in the visible light region of the electromagnetic spectrum. For example, the camera can image in the infrared light region of the electromagnetic spectrum. For example, the camera can image light having polarization, such as via a polarized filter that can also help reduce glare.

Notably, additional cameras can also be used to image the fluid volume of the wafer bath. For example, more than 1 of the camera can be used to generate 3D images. That is, when more than one camera is used to obtain the video data, the video data can include two streams of frames that can be correlated over time in order to describe the movement of the object (bubble) in more than one plane of the fluid volume. For example, with respect to the fluid having a general direction of flow from one side of the wafer bath to an opposite side of the wafer bath, an x-axis can be parallel to the direction of the flow, a y-axis can be orthogonal to the direction of the flow and also oriented along a vertical direction, and a z-axis can be orthogonal to the direction of the flow and also oriented along a horizontal or lateral direction. A first camera can describe a movement of the bubble in a plane parallel to the direction of the flow (x-axis) and also along the y-axis, and a second camera can describe a movement of the same bubble in a plane orthogonal to the direction of the flow (yz plane). Therefore, while the first camera alone can only describe the bubble movement along the x- and y-axes, the second camera can describe the bubble movement through the volume along the z-axis.

In an embodiment, the imaging device can be accompanied by a light source having corresponding emission wavelength range that the imaging device can detect. For example, the light source can have a wavelength range in the visible light region. For example, the light source can have a wavelength range in the infrared light region. For example, the light source can emit polarized light or be adjusted using a polarized filter to modify the polarization of the light detected by the imaging device. For example, the light source can emit a wavelength range of light that is chemical-based wavelength targeting. For example, the light source can be a laser. For example, the light source can emit sheets of light (visible, IR, etc.) configured to illuminate the fluid volume in a target plane along a target depth or dimension, such as an xy-plane disposed along a center of the bath. In doing so, a target bubble can be detected and monitored while illuminated in the xy-plane at the target depth, but detection and monitoring can stop once the target bubble is no longer disposed and illuminated in the xy-plane at the target depth (e.g., the target bubble moves some distance along the z-direction). This lighting modality can help filter out determined bubble metrics that are not confined to a single plane. The aforementioned can be leveraged to assist in the goals of step S310.

In an embodiment, at step S310, an object in a frame of the video data can be detected. The object can be, for example, a bubble. The detection of the bubble can be using, for example, computer vision. The inspected frame by frame stream of video data can be used by a computing device having processing circuitry, such as a CPU and/or a GPU, to identify the bubble. In an embodiment, the computing device can employ pattern recognition algorithms to detect and identify the bubble, the perimeter of the bubble, and/or a portion of the bubble. A variety of pattern recognition algorithms can be used, such as Artificial Neural Networks (ANN), Generative Adversarial Networks (GAN), thresholding, SVM (Support Vector Machines) or any classification and pattern recognition algorithm available conducive to computer vision. Computer vision techniques can be artificial intelligence techniques that train computers or models to interpret and understand visual data. In an example, the computer vision techniques can be an image recognition task, a semantic segmentation task, and the like.

In an example, the processor-based computer vision operation can include sequences of filtering operations, with each sequential filtering stage acting upon the output of the previous filtering stage. For instance, when the processor (processing circuitry) is/includes a GPU, these filtering operations can be carried out by fragment programs. One filtering technique includes applying a moving median filter by frame. The filtering technique can filter the video data through time, frame by frame, based on a window of a number of frames. For each frame, a median for each pixel within the frame can be determined across a set number of frames based on a size of the window. The median value for each pixel can be removed from each pixel to remove possible background data and noise. The window size for the number of frames can be adjusted to increase accuracy by either removing additional unwanted data or remove less needed data while filtering. In addition, a threshold filter can also be applied, which can remove data within each pixel based on either a lower or an upper threshold value, or both.

In an embodiment, the detection of the bubble in the video data can occur in a frame buffer of the GPU. In an embodiment, the detection of the bubble can be partially or entirely assisted via manual user input. That is, a user or operator can view the video data displayed on a display and select the bubble for detection and tracking, or de-select automatically detected bubbles when the detection is incorrect or a false-positive. Notably, the adjustments by the user can be used as training data for training a model and improving an accuracy of the model. Similarly, confirmations by the user that automatic detections and tracking by the model are correct can be used as training data for training the model. Synthetic or verified datasets including accurate detections and tracking of bubbles can also be used as training data for training the model.

In an embodiment, the previously described various imaging modalities and lighting modalities can be used to detect the bubble. For example, polarized light can be captured by a camera with a polarized filter, which can appear different when reflected off a bubble compared to the bulk fluid in the wafer bath. As such, a contrast between the bubble polarization and the fluid polarization can be leveraged to determine or detect the presence of the bubble. For example, an IR reflectance of the bubble can be different than an IR reflectance of the bulk fluid. As such, a contrast between the bubble IR reflectance and the fluid IR reflectance can be leveraged to determine or detect the presence of the bubble. For example, the bubble appearing in the illuminated sheet of light can result in a positive detection result until the bubble moves out of the plane of the sheet of light. When the light is visible light, an edge or outline of the bubble can be pronounced compared to the surrounding bulk fluid as well as a center area of the bubble, and, for example, edge detection can be used to detect the bubble. The edge detection process can include applying a Laplace transform to the frame being analyzed. This can result in an image having edges of the object converted to a binary value based on a transition from an outside of the object to an inside of the object. That is to say, anywhere there is an object edge, the object edge will appear highly contrasted. For example, edges of the object can be converted to white lines, while everything else is converted to black, or vice versa.

In an embodiment, once filtering has been applied, pixels within each frame can be determined that include data for bubble detection. In applying filtering, much of the remaining data can include bubble data within the bath. The pixels that still include data within each frame can be determined. Based on the remaining pixels and the corresponding location within each frame, the bubbles can be detected by grouping pixels together. Various thresholds can be applied when determining the grouping of pixels, such as a distance between pixels, a minimum and maximum number of pixels, and a minimum and maximum overall size of a grouping of pixels. Once pixels are grouped together, each set of pixels can be set as a bubble within the frame.

In an embodiment, at step S315, metrics for the object (bubble) can be determined. For example, the metrics can include a size and displacement or movement. The metrics can also include, for example, an overlap of an updated bubble position with a previous bubble position, a change in size, a speed of the bubble (absolute and relative to the flow rate of the fluid), bubble survival rate, bubble coalescing, bubble cavitation, the coordinates of the outer edge of the bubble, or a combination of the aforementioned, among others.

In an embodiment, at step S320, a determination can be made whether additional objects are detected in the current frame. As previously mentioned, more than one bubble can be disposed in a frame, and therefore detection and tracking of all bubbles can proceed. Thus, when additional objects are disposed in the frame, the method 300 can return to step S315 and determine metrics for all the detected objects. When additional objects are not disposed in the frame (or all objects have been detected and the metrics for all the objects have been determined), the method 300 can proceed to step S325.

In an embodiment, at step S325, the object can be detected in a subsequent frame of the video data, similar to step S310. When more than one object was detected in the previous frame, all of the objects can be detected again in the subsequent frame, except when any of the objects was determined to not be disposed in the subsequent frame anymore.

In an embodiment, at step S330, a determination can be made whether the object is in the current frame (which in this case is now the subsequent frame to the frame of steps S310 to S320). When the object is not detected in the current frame, the method 300 can end. When the object is detected in the current frame, the method 300 can proceed to step 335.

In an embodiment, at step S335, the metrics for the object in the current frame can be determined, similar to step S315.

In an embodiment, at step S340, a determination can be made whether additional objects are detected in the current frame. When additional objects are disposed in the current frame, the method 300 can return to step S335 and determine metrics for all the detected objects. When additional objects are not disposed in the current frame (or all objects have been detected and the metrics for all the objects have been determined), the method 300 can return to step S325 where the method continues to loop to analyze frames until the object is no longer detected.

Returning to FIG. 1C with reference to the method 300 of FIG. 3A, a similar example is shown but with multiple bubbles.

FIG. 1C is a schematic of multiple bubbles detected moving through a fluid, according to an embodiment of the present disclosure. In an embodiment, the first frame 191 now includes a first bubble 110a and a second bubble 110b, which can be detected (e.g., by the computing device) in step S310. In step S315, the first bubble 110a metrics can be determined, such as a first position of the first bubble 110a and a first size of the first bubble 110a. At step S320, since the first frame 191 now includes the second bubble 110b, the method 300 can return to step S315 and determine the metrics of the second bubble 110b, such as a first position of the second bubble 110b and a first size of the second bubble 110b. Upon return to step S320, since no other objects besides the first bubble 110a and the second bubble 110b are disposed in the first frame 191, the method 300 can proceed to step S325. That is, the first bubble 110a and the second bubble 110b can be imaged again in the second frame 192 and detected again in the second frame 192. At step S330, since the first bubble 110a is detected in the second frame 192, the metrics of the first bubble 110a can be determined for the second frame 192. The metrics of the first bubble 110a for the second frame 192 can be, for example, a second position of the first bubble 110a and a second size of the first bubble 110a. At step S340, since the second frame 192 now includes the second bubble 110b, the method 300 can return to step S335 and determine the metrics of the second bubble 110b, such as a second position of the second bubble 110b and a second size of the second bubble 110b.

Upon return to step S340, since no other objects besides the first bubble 110a and the second bubble 110b are disposed in the second frame 192, the method 300 can return to step S325. That is, the first bubble 110a and the second bubble 110b can be imaged again in the third frame 193 and detected again in the third frame 193. The method 300 can proceed through steps S330 to S340 again for the first bubble 110a and the second bubble 110b in the third frame 193. Upon return to step S340 since no other objects besides the first bubble 110a and the second bubble 110b are disposed in the third frame 193, the method 300 can return to step S325 where a fourth frame 194 can be imaged for object detection. However, as shown, the fourth frame 194 can include no objects. Then, in step S330, since no objects are detected in the fourth frame 194, the method 300 can end.

Additionally or alternatively, the detection and tracking for the objects need not cover an entire area of a frame of the video data.

To this end, FIG. 3B is a flow chart for a sub-method for detection in a region of interest (ROI), according to an embodiment of the present disclosure. In an embodiment, only a portion of the frame can be analyzed, which can help improve efficiency and accuracy of the method 300. In particular, the ROI can be an area that is a portion of or smaller than an area of the entire frame. In an embodiment, the ROI can be a predetermined portion of the frame. For example, the ROI can always be a center area of the frame having an area that is 25% of the frame area. In an embodiment, the ROI can be a customized portion of the frame. For example, a first set of frames for bubble tracking can include a first bubble detected in an upper-left quadrant of the frame area, while a second set of frames for bubble tracking can include a second bubble detected in a lower-right quadrant of the frame area. Therefore, a first ROI is the upper-left quadrant while a second ROI is the lower-right quadrant.

Thus, in an embodiment, at step S310a, a ROI can be determined in the frame.

In an embodiment, at step S310b, filtering, thresholding, imaging modality, and/or lighting modality can be applied or adjusted. As previously described, the detection of the objects in the frame can occur via various methods and step S310b is included to repeat the application of said various methods to the ROI.

In an embodiment, at step S310c, the object in the ROI can be detected.

In an embodiment, at step S310d, a determination can be made whether there is an additional ROI for analysis. Since there can be multiple objects in a frame, there can similarly be multiple ROIs in a frame. For example, the first bubble can be detected in the upper-left quadrant of the frame area (the first ROI) and the second bubble can be detected in the bottom-right quadrant of the frame area (the second ROI). Thus, the first ROI can be processed, then the sub-method can return to step S310a and the second ROI can be processed. When there is no additional ROI in the frame, the sub-method can end.

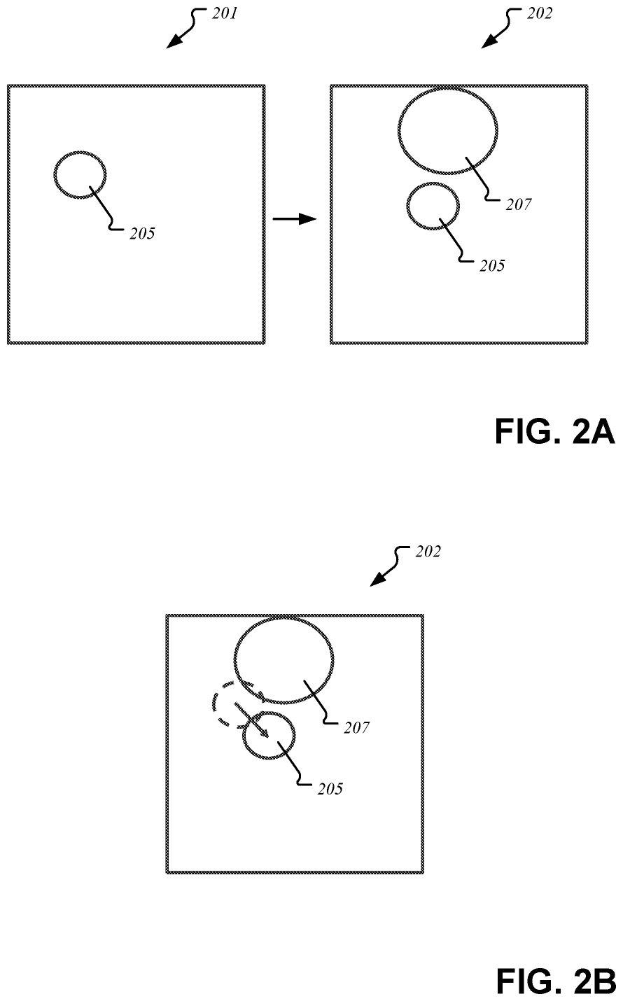

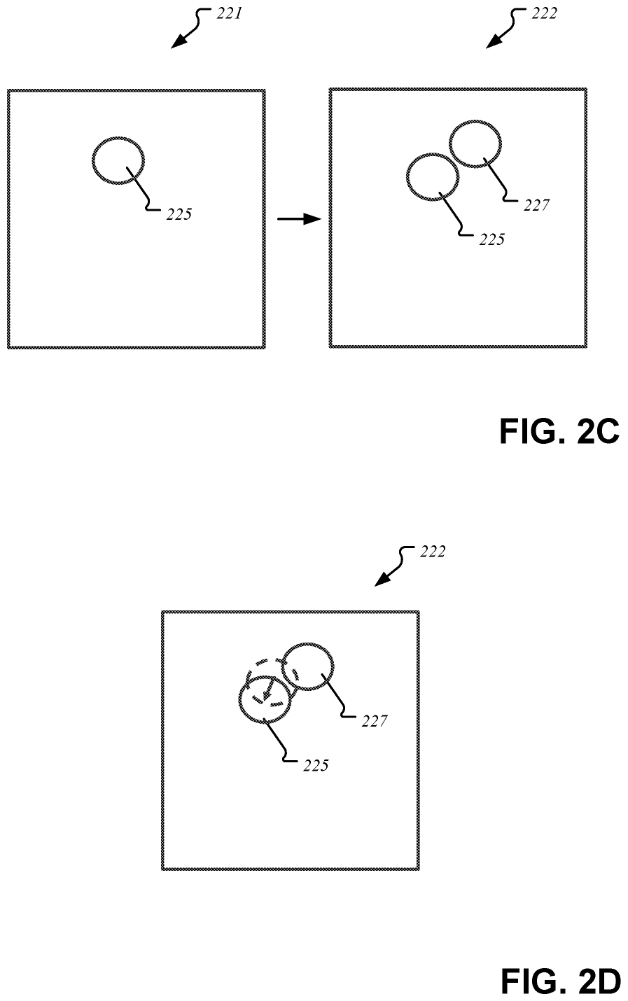

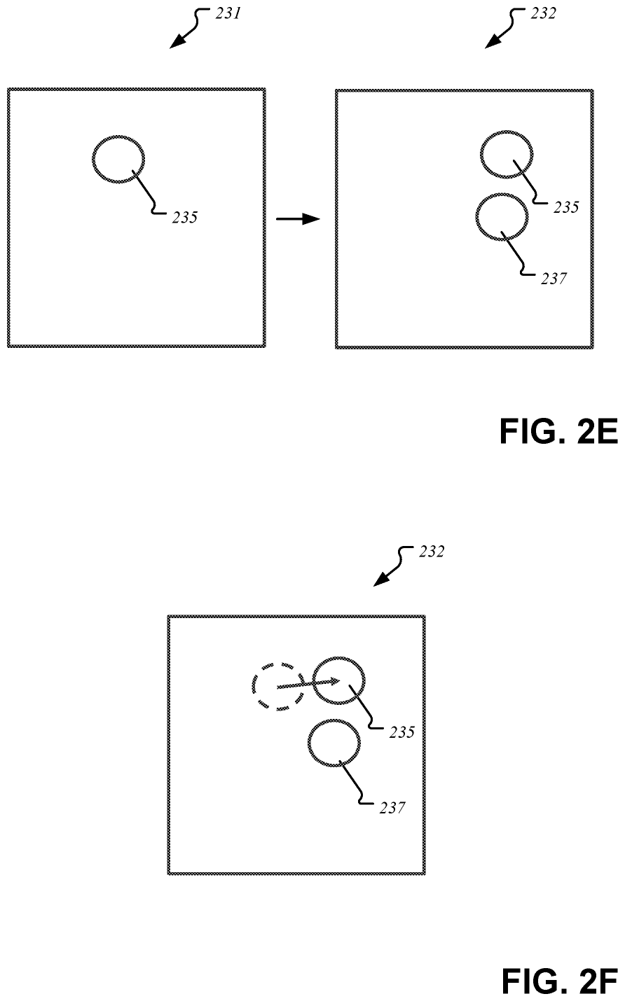

Additional examples of bubble detection are described herein according to FIGS. 2A through 2F with reference to the flow charts of FIGS. 3C to 3F.

FIG. 2A is a schematic of bubbles detected across frames, according to an embodiment of the present disclosure. FIG. 2B is a schematic of detecting and tracking a bubble based on size metrics, according to an embodiment of the present disclosure.

FIG. 3C is a flow chart for a sub-method of detecting objects in a frame, according to an embodiment in the present disclosure.

In an embodiment, a bubble 205 can be detected in a first frame 201 in FIG. 2A. In a second frame 202, which can be a subsequent frame to the first frame 201, the bubble 205 can be detected again, along with a new bubble 207. In the first frame 201, the bubble 205 can have a first position and a first diameter. In the second frame 202, the bubble 205 can have a second position and a second diameter. In the second frame 202, the new bubble 207 can have a first position and a first diameter. The new bubble 207 can be, for example, a bubble generated between the capture or imaging of the first frame 201 and the second frame 202. Notably, although the two bubbles have been identified and labeled, this can be a difficult goal to achieve for the computing device. That is, upon initially analyzing the second frame 202, the identities of the two bubbles can be unknown and the computing device can determine the identities of the two bubbles using, for example, the sub-method of FIG. 3C.

To this end, in an embodiment, in step S330a, for each object detected in a frame, an object (updated object) can be detected in a subsequent frame. For the bubble 205 in the first frame 201, this includes detecting at least one bubble in the second frame 202.

In an embodiment, in step 330c, a probability of each detected object being the subsequent object location can be determined based on metrics of the object. For the bubble 205 and the new bubble 207 (assuming identities are not known), a probability of the bubble 205 can be determined based on the second position and the second diameter of the bubble 205 and a probability of the new bubble 207 can be determined based on the first position and the first diameter of the new bubble 207. For example, a diameter difference between the first diameter of the bubble 205 and the second diameter of the bubble 205 can be determined, a diameter difference between the first diameter of the bubble 205 and the first diameter of the new bubble 207 can be determined, and a comparison of the two diameter differences can be performed. Notably, since a size (diameter) of a bubble can change minimally between two subsequent frames, a small diameter difference can correspond to a higher probability of the subsequent detected bubble being the true identity of the bubble from the previous frame. Therefore, since the diameter difference for the new bubble 207 compared to the bubble 205 in the first frame 201 is large and greater than the diameter difference for the bubble 205 in the second frame 202 compared to the bubble 205 in the first frame 201, the bubble 205 in the second frame 202 has a higher probability of being the true identity (and position) of the bubble 205 after movement between the first frame 201 and the second frame 202.

In an embodiment, in step S330d, the subsequent object location can be determined. For example, the location of the bubble 205 after movement from the first frame 201 to the second frame 202 can be determined to be the second location of the bubble 205 in the second frame 202 based on the determined probabilities. As shown in FIG. 2B, the arrow shows the movement of the bubble 205 from the first frame 201 to the second frame 202 with the dashed outline denoting the previous position (the first position) of the bubble 205.

FIG. 2C is a schematic of bubbles detected across frames, according to an embodiment of the present disclosure. FIG. 2D is a schematic of detecting and tracking a bubble based on overlap, according to an embodiment of the present disclosure.

FIG. 3D is a flow chart for a sub-method of detecting objects in a frame, according to an embodiment in the present disclosure.

In an embodiment, a bubble 225 can be detected in a first frame 221 in FIG. 2C. In a second frame 222, which can be a subsequent frame to the first frame 221, the bubble 225 can be detected again, along with a new bubble 227. In the first frame 221, the bubble 225 can have a first position and a first diameter. In the second frame 222, the bubble 225 can have a second position and a second diameter. In the second frame 222, the new bubble 227 can have a first position and a first diameter. The new bubble 227 can be, for example, a bubble generated between the capture or imaging of the first frame 221 and the second frame 222. Again, although the two bubbles have been identified and labeled, this can be a difficult goal to achieve for the computing device. That is, upon initially analyzing the second frame 222, the identities of the two bubbles can be unknown and the computing device can determine the identities of the two bubbles using, for example, the sub-method of FIG. 3D.

To this end, in an embodiment, in step S330e, for each object detected in a frame, an overlapping object (updated overlapping object) can be detected in a subsequent frame. For the bubble 225 in the first frame 221, this includes detecting at least one overlapping bubble in the second frame 222.

In an embodiment, in step 330g, a probability of each detected object being the subsequent object location can be determined based on metrics of the object. For the bubble 225 and the new bubble 227 (assuming identities are not known), a probability of the bubble 225 can be determined based on the second position and the second diameter of the bubble 225 and a probability of the new bubble 227 can be determined based on the first position and the first diameter of the new bubble 227. For example, since the first position and the first diameter of the bubble 225 has been determined, an overlap (absolute value, percentage, ratio, etc.) between the bubble 225 in the first frame 221 and the bubble 225 in the second frame 222 can be determined, an overlap between the bubble 225 in the first frame 221 and the new bubble 227 in the second frame 222 can be determined, and a comparison of the two overlaps can be performed. Notably, since a position of a bubble can change minimally between two subsequent frames, a large overlap can correspond to a higher probability of the subsequent detected bubble being the true identity of the bubble from the previous frame. Therefore, since the overlap for the new bubble 227 and the bubble 225 in the first frame 221 is small and less than the overlap for the bubble 225 in the second frame 222 and the bubble 225 in the first frame 221, the bubble 225 in the second frame 222 has a higher probability of being the true identity (and position) of the bubble 225 after movement between the first frame 221 and the second frame 222.

In an embodiment, in step S330h, the subsequent object location can be determined. For example, the location of the bubble 225 after movement from the first frame 221 to the second frame 222 can be determined to be the second location of the bubble 225 in the second frame 222 based on the determined probabilities. As shown in FIG. 2D, the arrow shows the movement of the bubble 225 from the first frame 221 to the second frame 222 with the dashed outline denoting the previous position (the first position) of the bubble 225.

FIG. 2E is a schematic of bubbles detected across frames, according to an embodiment of the present disclosure. FIG. 2F is a schematic of detecting and tracking a bubble based on distance, according to an embodiment of the present disclosure.

FIG. 3E is a flow chart for a sub-method of detecting objects in a frame, according to an embodiment in the present disclosure.

In an embodiment, a bubble 235 can be detected in a first frame 231 in FIG. 2E. In a second frame 232, which can be a subsequent frame to the first frame 231, the bubble 235 can be detected again, along with a new bubble 237. In the first frame 231, the bubble 235 can have a first position and a first diameter. In the second frame 232, the bubble 235 can have a second position and a second diameter. In the second frame 232, the new bubble 237 can have a first position and a first diameter. The new bubble 237 can be, for example, a bubble generated between the capture or imaging of the first frame 231 and the second frame 232. Again, although the two bubbles have been identified and labeled, this can be a difficult goal to achieve for the computing device. That is, upon initially analyzing the second frame 232, the identities of the two bubbles can be unknown and the computing device can determine the identities of the two bubbles using, for example, the sub-method of FIG. 3E.

To this end, in an embodiment, in step S330i, for each object detected in a frame, an object (updated object) can be detected in a subsequent frame within a predetermined distance from the original position in the previous frame. For the bubble 235 in the first frame 231, this includes detecting at least one bubble in the second frame 232 within a predetermined distance of the bubble 235 in the first frame 231.

In an embodiment, in step 330k, a probability of each detected object being the subsequent object location can be determined based on metrics of the object. For the bubble 235 and the new bubble 237 (assuming identities are not known), a probability of the bubble 235 can be determined based on the second position and the second diameter of the bubble 235 and a probability of the new bubble 237 can be determined based on the first position and the first diameter of the new bubble 237. For example, since the first position and the first diameter of the bubble 235 has been determined, a distance (center to center, edge to edge, etc.) or change in position between the bubble 235 in the first frame 231 and the bubble 235 in the second frame 232 can be determined, a distance or change in position between the bubble 235 in the first frame 231 and the new bubble 237 in the second frame 232 can be determined, and a comparison of the two distances or changes in position can be performed. Notably, since a position of a bubble can change minimally between two subsequent frames, a small distance can correspond to a higher probability of the subsequent detected bubble being the true identity of the bubble from the previous frame. Therefore, since the distance between the new bubble 237 and the bubble 235 in the first frame 231 is large and greater than the distance between the bubble 235 in the second frame 232 and the bubble 235 in the first frame 231, the bubble 235 in the second frame 232 has a higher probability of being the true identity (and position) of the bubble 235 after movement between the first frame 231 and the second frame 232.

In an embodiment, in step S3301, the subsequent object location can be determined. For example, the location of the bubble 235 after movement from the first frame 231 to the second frame 232 can be determined to be the second location of the bubble 235 in the second frame 232 based on the determined probabilities. As shown in FIG. 2F, the arrow shows the movement of the bubble 235 from the first frame 231 to the second frame 232 with the dashed outline denoting the previous position (the first position) of the bubble 235.

In an embodiment, a combination of the aforementioned techniques can be used to determine the probabilities and determine the subsequent object location.

For example, for a first pair of objects, an overlap can be large while a diameter difference can be large as well. For a second pair of objects, an overlap can be slightly less than the first pair, but the diameter difference can be very small. The diameter difference can have a greater weight than the overlap after considering the probabilities for both pairs. Thus, for such a scenario, the second pair of objects can be the corresponding initial and subsequent positions of the object.

For example, for a first pair of objects, a distance can be small while a diameter difference can be large. For a second pair of objects, a distance can be slightly greater than the first pair, but the diameter difference can be very small. The diameter difference can have a greater weight than the distance after considering the probabilities for both pairs. Thus, for such a scenario, the second pair of objects can be the corresponding initial and subsequent positions of the object.

For example, for a first pair of objects, a distance can be very large while a diameter difference can be small. For a second pair of objects, a distance can be significantly smaller than the first pair, but the diameter difference can be slightly greater than the first pair. The magnitude of the distance difference can lower the probability sufficiently for the first pair even to be ruled out even though the diameter difference of the second pair is slightly greater than the first pair of objects. Thus, for such a scenario, the second pair of objects can be the corresponding initial and subsequent positions of the object. Of course, for any combination of techniques, an outcome can change based on the applied weights or preferences to one technique's result over another.

In an embodiment, the number of detected objects in a subsequent frame can be fewer than the number of detected objects in the previous frame. Again, a probability can be applied based on the determined metrics.

To this end, FIG. 3F is a flow chart for a sub-method of detecting objects in a frame, according to an embodiment in the present disclosure. In an embodiment, at step S330m, the number of detected objects in a subsequent frame is fewer than the number of detected objects in the previous frame.

In an embodiment, at step S330n, a probability of each detected object being the subsequent object location can be determined based on metrics of the object. The same methods and techniques previously described can be applied. Here, since there are fewer objects in the subsequent frame, a comparison of all the pairs can be performed and the pair having the lowest probability can be eliminated. This can eliminate one of the extra objects (bubbles) in the previous frame that should not be tracked further (e.g., a bubble popped between frames). The remaining pairs with the highest probabilities can continue to be tracked.

The metrics for the bubbles tracked through time can be used to elucidate the effectiveness of processing recipes. For example, a first recipe having a high flow rate can result in tracked bubbles having a high movement or speed and a low bubble survivability while yielding a corresponding poor wafer quality after etching. In contrast, a second recipe having a low flow rate can result in tracked bubbles having a low movement or speed and a high bubble survivability while yielding a corresponding higher wafer quality after etching. The first recipe can be adjusted to produce tracked bubbles with movement and survivability in between the first recipe and the second recipe, and the wafer quality processed using the updated recipe can be determined to determine a correlation between the changes in the recipe, changes in the wafer quality, and metrics of the bubbles. Upon iteration and determining a particular metric of the bubbles results in improved wafer quality, the recipe can be adjusted again to optimize the particular metric of the bubbles that results in better wafer quality.

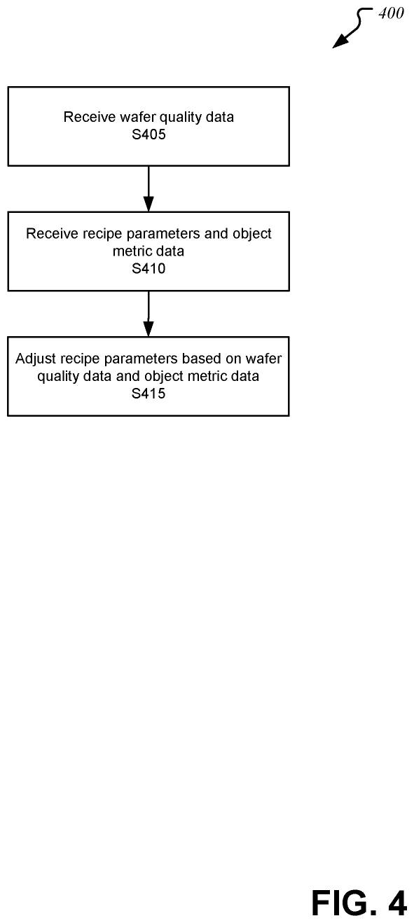

FIG. 4 is a flow chart describing a method 400 of adjusting a semiconductor manufacturing process based on tracked bubble metrics, according to an embodiment of the present disclosure. In an embodiment, in step S405, data relating to wafer quality can be received.

In an embodiment, in step S410, parameters for a recipe and corresponding metric data for an object (e.g., tracked bubbles) can be received.

In an embodiment, in step S415, the parameters for the recipe can be adjusted based on the received wafer quality data and the object metric data.

A summary of the aforementioned methods is described herein.

In an embodiment, video recording of a wafer bath having a fluid through time can provide insight and observation of processes occurring within the bath. One process of interest includes the location and movement of bubbles within the bath through time. One step of the process includes determining the bubbles within the bath through time by detecting the individual bubbles. Once the bubbles can be detected, the bubbles can be tracked throughout the bath through time in order to determine the location and movement (displacement, speed, etc.) of each individual bubble. Analysis methods can be developed for each of these processes in order to help automate the bubble detection and tracking for different datasets.

To determine the number of bubbles and the location of each bubble within the bath through time, the described method accurately detects possible bubbles in the bath. One technique for this determination includes determining an area or region of interest within the video data (the frames) to search and detect the bubbles. For any area within the video data that is not needed or when it is determined that no bubbles will occur within a portion of the frame, then analysis need not be performed in the determined portion of the frame.

To analyze the video data and detect bubbles, different filtering techniques can be used to help more accurately detect the bubbles. One filtering technique includes applying a moving median filter by frame. The filtering technique filters the video data through time, frame by frame, based on a window of a number of frames. For each frame, the median for each pixel within the frame is determined across a set number of frames based on the window size. This median value for each pixel is then removed from each pixel to remove possible background data and noise. The window size for the number of frames can be adjusted to increase accuracy by either removing additional unwanted data or remove less needed data while filtering. In addition, a threshold filter can also be applied, which can remove data within each pixel based on either a lower or an upper threshold value, or both.

Once filtering has been applied and, optionally, the ROI is determined, pixels within each frame can be determined that include data for bubble detection. In determining the ROI and applying filtering, much of the remaining data can include bubble data within the bath. The pixels that still include data within each frame can be determined. Based on remaining pixels and the corresponding location within each frame, the bubbles are detected by grouping pixels together. Various thresholds can be applied when determining the grouping of pixels, such as distance between pixels, minimum and maximum number of pixels, and minimum and maximum overall size of grouping of pixels. Once pixels are grouped together, each set of pixels are then set as a bubble within the frame. Once a bubble is determined, metrics such as the center of the bubble location, the size of the bubble, and the coordinates of the outer edge of the bubble can be calculated for each bubble.

For each bubble in a given frame, it is then determined whether the bubble can be tracked in the next, subsequent frame. The determination includes detecting whether the bubble overlaps with any bubbles within the subsequent frame based on a size and edge of the bubbles (e.g., FIG. 1A). In addition, thresholds can be set to determine a minimum overlap of bubbles across frames or a minimum distance that bubbles are from each other to be set as the same bubble tracked across frames (e.g., FIG. 1B). For a given frame and bubble, when the bubble was tracked in previous frames, then an overall direction of movement can be applied to help with searching and tracking of the bubble in the subsequent frame. For each bubble in the frame, it is then determined whether the bubble is able to be tracked in the next frame.

When tracking the bubbles across the frames, some bubbles can be detected to be tracked by multiple bubbles between frames. A check can be used to determine, for each bubble in the subsequent frame, whether the bubble detected can be tracked by multiple bubbles in the current frame. Upon determining the bubble can be tracked by multiple bubbles in the current frame, a determination can be made for which bubble in the current frame is the best match for the bubble in the subsequent frame. Methods such as best size matching between the bubbles (e.g., FIG. 2A), the closest location match (e.g., FIG. 2E), and/or the overlap between the bubbles (e.g., FIG. 2C) can be used to determine which bubble in the current frame is the best match. In addition, when multiple bubbles in the subsequent frame are detected to be tracked for a single bubble in the current frame, a determination can be made for which bubble in the subsequent frame is the best match for the current bubble. The previous methods can be used to also determine the best match across multiple bubbles in the subsequent frame for the current bubble.

When a bubble cannot be tracked in the subsequent frame, a determination can be made that the bubble is last tracked at the location and frame in time and is no longer tracked in subsequent frames. When a bubble was not tracked in a previous frame, then the bubble can be set as a new bubble to be tracked. In addition, based on the area of analysis or ROI, a determination can be made that a given bubble has left or entered the ROI.

Through these techniques, the disclosed method can be used to detect and track bubbles in a frame of video data, or a portion of the frame, and throughout frames in time. The tracking of each bubble can give a location throughout time and when and where the tracking of the bubble started and ended. In addition, the size of the bubble, the movement within the bath, and the rate at which it is moving throughout time (among other metrics) can be determined based on the detection and tracking. Overall metrics for the bubbles can also be calculated, such as the number of bubbles detected through time and the overall location of the bubbles.

Embodiments of the subject matter and the functional operations described in this specification can be implemented by digital electronic circuitry, in tangibly embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory program carrier for execution by, or to control the operation of data processing apparatus. The computer storage medium can be a machine-readable storage device, a machine-readable storage substrate, a random or serial access memory device, or a combination of one or more of them.

The term “data processing apparatus” refers to data processing hardware and may encompass all kinds of apparatus, devices, and machines for processing data, including by way of example a programmable processor, a computer, or multiple processors or computers. The apparatus can also be or further include special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, Subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA an ASIC.

Computers suitable for the execution of a computer program include, by way of example, general or special purpose microprocessors or both, or any other kind of central processing unit. Generally, a CPU will receive instructions and data from a read-only memory or a random access memory or both. Elements of a computer are a CPU for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few. Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more Such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients (user devices) and servers. A client and server are generally remote from each other and typically interact through a communication network. The relationship of client and server arises by virtue of computer programs running on the respective computers and having a client-server relationship to each other. In an embodiment, a server transmits data, e.g., an HTML page, to a user device, e.g., for purposes of displaying data to and receiving user input from a user interacting with the user device, which acts as a client. Data generated at the user device, e.g., a result of the user interaction, can be received from the user device at the server.

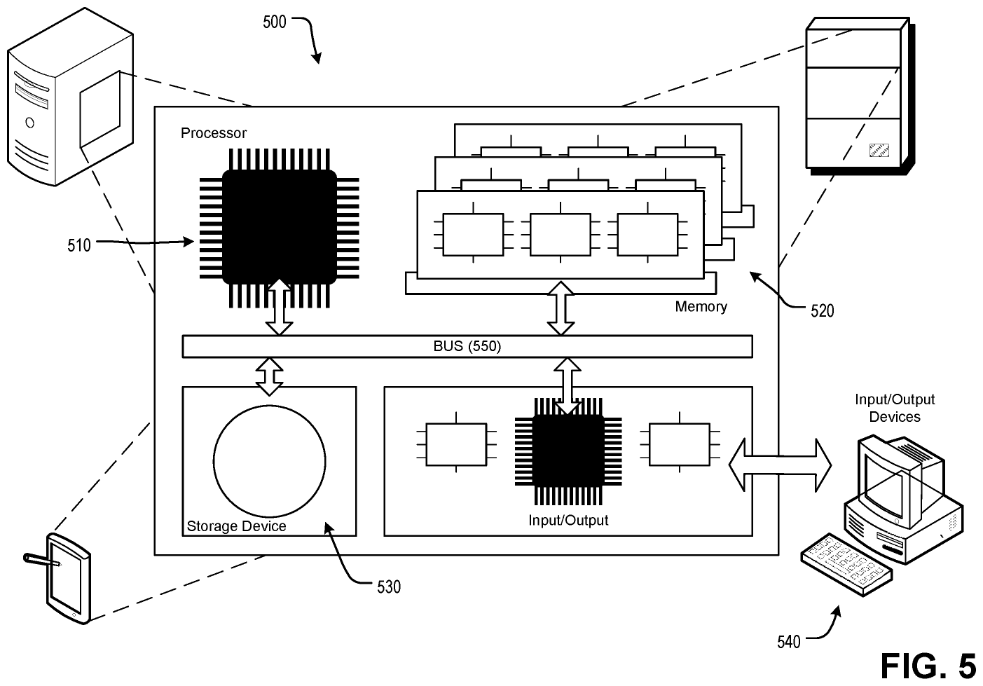

An example of a type of computer is shown in FIG. 5. The computer 500 can be used for the operations described in association with any of the computer-implement methods described previously, according to one implementation. For example, the computer 500 can be an example of the computing device. The computer 500 includes processing circuitry, as discussed above. The computer 500 may include other components not explicitly illustrated in FIG. 5 such as a CPU, GPU, frame buffer, etc. The processing circuitry includes one or more of the elements discussed next with reference to FIG. 5. In FIG. 5, the computer 500 includes a processor 510, a memory 520, a storage device 530, and an input/output device 540. Each of the components 510, 520, 530, and 540 are interconnected using a system bus 550. The processor 510 is capable of processing instructions for execution within the system 500. In one implementation, the processor 510 is a single-threaded processor. In another implementation, the processor 510 is a multi-threaded processor. The processor 510 is capable of processing instructions stored in the memory 520 or on the storage device 530 to display graphical information for a user interface on the input/output device 540.

The memory 520 stores information within the computer 500. In one implementation, the memory 520 is a computer-readable medium. In one implementation, the memory 520 is a volatile memory unit. In another implementation, the memory 520 is a non-volatile memory unit.

The storage device 530 is capable of providing mass storage for the computer 500. In one implementation, the storage device 530 is a computer-readable medium. In various different implementations, the storage device 530 may be a floppy disk device, a hard disk device, an optical disk device, or a tape device.

The input/output device 540 provides input/output operations for the computer 500. In one implementation, the input/output device 540 includes a keyboard and/or pointing device. In another implementation, the input/output device 540 includes a display unit for displaying graphical user interfaces.

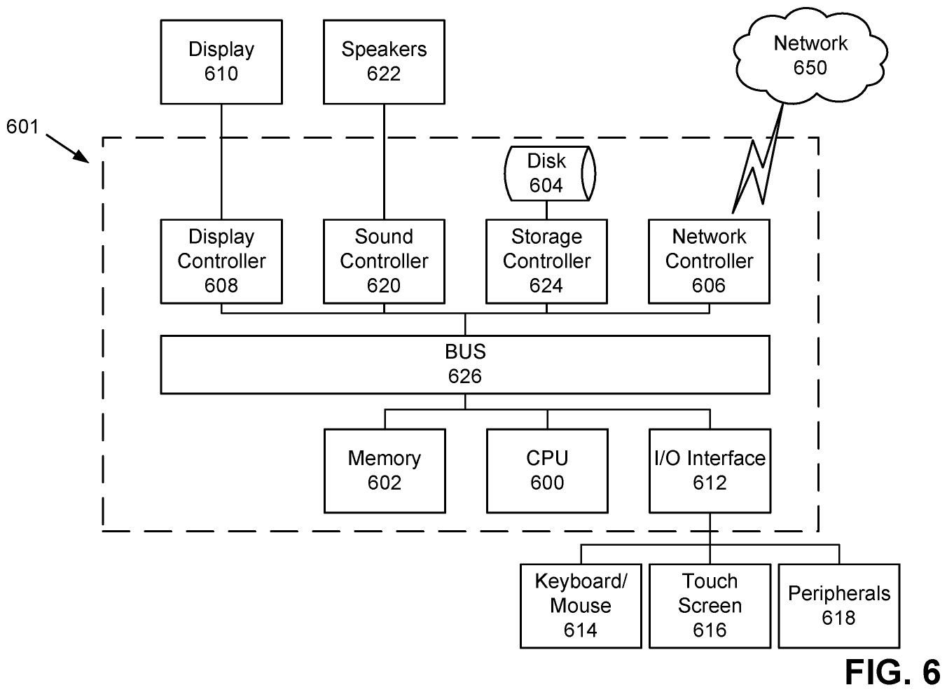

Next, a hardware description of a device 601 according to exemplary embodiments is described with reference to FIG. 6. In FIG. 6, the device 601, which can be the above described processing devices, includes processing circuitry, as discussed above. The processing circuitry includes one or more of the elements discussed next with reference to FIG. 6. The device 601, may include other components not explicitly illustrated in FIG. 6 such as a CPU, GPU, frame buffer, etc. In FIG. 6, the device 601 includes a CPU 600 which performs the processes described above/below. The process data and instructions may be stored in memory 602. These processes and instructions may also be stored on a storage medium disk 604 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the device 601 communicates, such as a server or computer.

Further, the claimed advancements may be provided as a utility application, background daemon, or component of an operating system, or combination thereof, executing in conjunction with CPU 600 and an operating system such as Microsoft Windows, UNIX, Solaris, LINUX, Apple MAC-OS and other systems known to those skilled in the art.

The hardware elements in order to achieve the device 601 may be realized by various circuitry elements, known to those skilled in the art. For example, CPU 600 may be a Xenon or Core processor from Intel of America or an Opteron processor from AMD of America, or may be other processor types that would be recognized by one of ordinary skill in the art. Alternatively, the CPU 600 may be implemented on an FPGA, ASIC, PLD or using discrete logic circuits, as one of ordinary skill in the art would recognize. Further, CPU 600 may be implemented as multiple processors cooperatively working in parallel to perform the instructions of the processes described above.

The device 601 in FIG. 6 also includes a network controller 606, such as an Intel Ethernet PRO network interface card from Intel Corporation of America, for interfacing with network 650, and to communicate with the other devices. As can be appreciated, the network 650 can be a public network, such as the Internet, or a private network such as an LAN or WAN network, or any combination thereof and can also include PSTN or ISDN sub-networks. The network 650 can also be wired, such as an Ethernet network, or can be wireless such as a cellular network including EDGE, 3G, 4G and 5G wireless cellular systems. The wireless network can also be WiFi, Bluetooth, or any other wireless form of communication that is known.

The device 601 further includes a display controller 608, such as a NVIDIA GeForce GTX or Quadro graphics adaptor from NVIDIA Corporation of America for interfacing with display 610, such as an LCD monitor. A general purpose I/O interface 612 interfaces with a keyboard and/or mouse 614 as well as a touch screen panel 616 on or separate from display 610. General purpose I/O interface also connects to a variety of peripherals 618 including printers and scanners.

A sound controller 620 is also provided in the device 601 to interface with speakers/microphone 622 thereby providing sounds and/or music.

The general purpose storage controller 624 connects the storage medium disk 604 with communication bus 626, which may be an ISA, EISA, VESA, PCI, or similar, for interconnecting all of the components of the device 601. A description of the general features and functionality of the display 610, keyboard and/or mouse 614, as well as the display controller 608, storage controller 624, network controller 606, sound controller 620, and general purpose I/O interface 612 is omitted herein for brevity as these features are known.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Embodiments of the present disclosure may also be as set forth in the following parentheticals.
(1) A semiconductor processing apparatus for detecting objects in a fluid, including: processing circuitry configured to receive video data including a plurality of frames, detect, in a first frame of the video data, a first object, determine first metrics for the first object in the first frame, the first metrics including a position of the first object and a size of the first object, detect, in a second frame of the video data, a second object, determine second metrics for the second object in the second frame, the second metrics including a position of the second object and a size of the second object, determine a first difference between the first metrics of the first object in the first frame and the second metrics of the second object in the second frame, and based on the determined first difference, determine whether the first object in the first frame is a same object as the second object in the second frame.
(2) The apparatus of (1), wherein the processing circuitry is further configured to receive data related to a quality of a wafer processed in the fluid using a corresponding first processing recipe defining a first set of parameters, and based on the wafer quality data, the first metrics, and the second metrics, adjust the first set of parameters of the first recipe to generate a second recipe.
(3) The apparatus of either (1) or (2), wherein the processing circuitry determines whether the first object in the first frame is the same object as the second object in the second frame based on the determined first difference by based on the determined first difference, assigning a probability value to the second object in the second frame defining a likelihood of the first object in the first frame being the same object as the second object in the second frame.
(4) The apparatus of any one of (1) to (3), wherein the processing circuitry is configured to determine the first difference by determining a difference between the size of the first object in the first frame and the size of the second object in the second frame.
(5) The apparatus of any one of (1) to (4), wherein the processing circuitry is configured to determine the first difference by determining a distance between the position of the first object in the first frame and the position of the second object in the second frame.
(6) The apparatus of any one of (1) to (5), wherein the processing circuitry is configured to determine the first difference by determining an area overlap between an area of the first object in the first frame and an area of the second object in the second frame.
(7) The apparatus of any one of (1) to (6), wherein the apparatus further comprises a first light source configured to emit light having a predetermined wavelength range; and an imaging device configured to obtain the video data by capturing the emitted light from the first light source, the imaging device being sensitive to the predetermined wavelength range of the emitted light.
(8) The apparatus of any one of (1) to (7), wherein the first light source is configured to emit light along a predetermined plane through a volume of the fluid, and the imaging device is configured to only capture the emitted light by the first light source along the predetermined plane through the volume of the fluid.
(9) The apparatus of any one of (1) to (8), wherein the processing circuitry is configured to detect the first object in the first frame and detect the second object in the second frame by applying, to each pixel in each frame of the video data, a filter to generate a transformed frame, and detecting, in the transformed frames, the first object and the second object.
(10) The apparatus of any one of (1) to (9), wherein the processing circuitry is further configured to after determining the second metrics for the second object in the second frame, determine whether additional objects are disposed in the second frame, upon determining additional objects are disposed in the second frame, detect, in the second frame, a third object, and determine third metrics for the third object in the second frame, the third metrics including a position of the third object and a size of the third object.
(11) The apparatus of any one of (1) to (10), wherein the processing circuitry is further configured to determine a second difference by determining a difference between the first metrics of the first object in the first frame and the third metrics of the third object in the third frame, and the processing circuitry determines whether the first object in the first frame is the same object as the second object in the second frame or the same object as the third object in the second frame based on the determined first difference and the determined second difference.
(12) The apparatus of any one of (1) to (11), wherein the processing circuitry determines whether the first object in the first frame is the same object as the second object in the second frame or the same object as the third object in the second frame based on the determined first difference and the determined second difference by based on the determined first difference, assigning a first probability value to the second object in the second frame defining a likelihood of the first object in the first frame being the same object as the second object in the second frame, based on the determined second difference, assigning a second probability value to the third object in the second frame defining a likelihood of the first object in the first frame being the same object as the third object in the second frame, and determining whether the first object in the first frame is the same object as the second object in the second frame or the same object as the third object in the second frame based on the second object or the third object having the higher probability value.
(13) The apparatus of any one of (1) to (12), wherein the processing circuitry is configured to detect the first object in the first frame by determining a first region of interest in an area of the first frame, the first region of interest including the first object disposed therein, and detecting, in the first region of interest, the first object.
(14) The apparatus of any one of (1) to (13), wherein the processing circuitry is configured to detect the second object in the second frame by determining a second region of interest in an area of the second frame, the second region of interest including the second object disposed therein, the second region of interest having a position and size within the area of the second frame that is the same as a position and size of the first region within the area of the first frame, and detecting, in the second region of interest, the second object.
(15) The apparatus of any one of (1) to (14), wherein the first object and the second object are bubbles.
(16) A method of detecting objects in a fluid in a semiconductor manufacturing apparatus, including receiving video data including a plurality of frames; detecting, in a first frame of the video data, a first object; determining first metrics for the first object in the first frame, the first metrics including a position of the first object and a size of the first object; detecting, in a second frame of the video data, a second object; determining second metrics for the second object in the second frame, the second metrics including a position of the second object and a size of the second object; determining a first difference between the first metrics of the first object in the first frame and the second metrics of the second object in the second frame; and based on the determined first difference, determining whether the first object in the first frame is a same object as the second object in the second frame.
(17) The method of (16), further including receiving data related to a quality of a wafer processed in the fluid using a corresponding first processing recipe defining a first set of parameters; and based on the wafer quality data, the first metrics, and the second metrics, adjusting the first set of parameters of the first recipe to generate a second recipe.
(18) The method of either (16) or (17), further including wherein whether the first object in the first frame is the same object as the second object in the second frame based on the determined first difference is determined by based on the determined first difference, assigning a probability value to the second object in the second frame defining a likelihood of the first object in the first frame being the same object as the second object in the second frame.
(19) The method of any one of (16) to (18), wherein determining the first difference is determined by determining a difference between the size of the first object in the first frame and the size of the second object in the second frame.
(20) The method of any one of (16) to (19), wherein determining the first difference is determined by determining a distance between the position of the first object in the first frame and the position of the second object in the second frame.
(21) The method of any one of (16) to (20), wherein determining the first difference is determined by determining an area overlap between an area of the first object in the first frame and an area of the second object in the second frame.
(22) A non-transitory computer-readable storage medium including executable instructions, which when executed by circuitry, cause the circuitry to perform a method of detecting objects in a fluid in a semiconductor manufacturing apparatus, including receiving video data including a plurality of frames; detecting, in a first frame of the video data, a first object; determining first metrics for the first object in the first frame, the first metrics including a position of the first object and a size of the first object; detecting, in a second frame of the video data, a second object; determining second metrics for the second object in the second frame, the second metrics including a position of the second object and a size of the second object; determining a first difference between the first metrics of the first object in the first frame and the second metrics of the second object in the second frame; and based on the determined first difference, determining whether the first object in the first frame is a same object as the second object in the second frame.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor processing apparatus for detecting objects in a fluid, comprising:
processing circuitry configured to
receive video data including a plurality of frames,
detect, in a first frame of the video data, a first object,
determine first metrics for the first object in the first frame, the first metrics including a position of the first object and a size of the first object,
detect, in a second frame of the video data, a second object,
determine second metrics for the second object in the second frame, the second metrics including a position of the second object and a size of the second object,
determine a first difference between the first metrics of the first object in the first frame and the second metrics of the second object in the second frame, and
based on the determined first difference, determine whether the first object in the first frame is a same object as the second object in the second frame.

2. The apparatus of claim 1, wherein the processing circuitry is further configured to
receive data related to a quality of a wafer processed in the fluid using a corresponding first processing recipe defining a first set of parameters, and
based on the wafer quality data, the first metrics, and the second metrics, adjust the first set of parameters of the first recipe to generate a second recipe.

3. The apparatus of claim 1, wherein the processing circuitry determines whether the first object in the first frame is the same object as the second object in the second frame based on the determined first difference by
based on the determined first difference, assigning a probability value to the second object in the second frame defining a likelihood of the first object in the first frame being the same object as the second object in the second frame.

4. The apparatus of claim 1, wherein the processing circuitry is configured to determine the first difference by determining a difference between the size of the first object in the first frame and the size of the second object in the second frame.

5. The apparatus of claim 1, wherein the processing circuitry is configured to determine the first difference by determining a distance between the position of the first object in the first frame and the position of the second object in the second frame.

6. The apparatus of claim 1, wherein the processing circuitry is configured to determine the first difference by determining an area overlap between an area of the first object in the first frame and an area of the second object in the second frame.

7. The apparatus of claim 1, wherein the apparatus further comprises
a first light source configured to emit light having a predetermined wavelength range; and
an imaging device configured to obtain the video data by capturing the emitted light from the first light source, the imaging device being sensitive to the predetermined wavelength range of the emitted light.

8. The apparatus of claim 7, wherein
the first light source is configured to emit light along a predetermined plane through a volume of the fluid, and
the imaging device is configured to only capture the emitted light by the first light source along the predetermined plane through the volume of the fluid.

9. The apparatus of claim 1, wherein the processing circuitry is configured to detect the first object in the first frame and detect the second object in the second frame by
applying, to each pixel in each frame of the video data, a filter to generate a transformed frame, and
detecting, in the transformed frames, the first object and the second object.

10. The apparatus of claim 1, wherein the processing circuitry is further configured to
after determining the second metrics for the second object in the second frame, determine whether additional objects are disposed in the second frame,
upon determining additional objects are disposed in the second frame, detect, in the second frame, a third object, and
determine third metrics for the third object in the second frame, the third metrics including a position of the third object and a size of the third object.

11. The apparatus of claim 10, wherein
the processing circuitry is further configured to determine a second difference by determining a difference between the first metrics of the first object in the first frame and the third metrics of the third object in the third frame, and
the processing circuitry determines whether the first object in the first frame is the same object as the second object in the second frame or the same object as the third object in the second frame based on the determined first difference and the determined second difference.

12. The apparatus of claim 11, wherein the processing circuitry determines whether the first object in the first frame is the same object as the second object in the second frame or the same object as the third object in the second frame based on the determined first difference and the determined second difference by
based on the determined first difference, assigning a first probability value to the second object in the second frame defining a likelihood of the first object in the first frame being the same object as the second object in the second frame,
based on the determined second difference, assigning a second probability value to the third object in the second frame defining a likelihood of the first object in the first frame being the same object as the third object in the second frame, and
determining whether the first object in the first frame is the same object as the second object in the second frame or the same object as the third object in the second frame based on the second object or the third object having the higher probability value.

13. The apparatus of claim 1, wherein the processing circuitry is configured to detect the first object in the first frame by
determining a first region of interest in an area of the first frame, the first region of interest including the first object disposed therein, and
detecting, in the first region of interest, the first object.

14. The apparatus of claim 13, wherein the processing circuitry is configured to detect the second object in the second frame by
determining a second region of interest in an area of the second frame, the second region of interest including the second object disposed therein, the second region of interest having a position and size within the area of the second frame that is the same as a position and size of the first region within the area of the first frame, and
detecting, in the second region of interest, the second object.

15. The apparatus of claim 1, wherein the first object and the second object are bubbles.

16. A method of detecting objects in a fluid in a semiconductor manufacturing apparatus, comprising:
receiving video data including a plurality of frames;
detecting, in a first frame of the video data, a first object;
determining first metrics for the first object in the first frame, the first metrics including a position of the first object and a size of the first object;
detecting, in a second frame of the video data, a second object;
determining second metrics for the second object in the second frame, the second metrics including a position of the second object and a size of the second object;
determining a first difference between the first metrics of the first object in the first frame and the second metrics of the second object in the second frame; and
based on the determined first difference, determining whether the first object in the first frame is a same object as the second object in the second frame.

17. The method of claim 16, further comprising:
receiving data related to a quality of a wafer processed in the fluid using a corresponding first processing recipe defining a first set of parameters; and
based on the wafer quality data, the first metrics, and the second metrics, adjusting the first set of parameters of the first recipe to generate a second recipe.

18. The method of claim 16, wherein whether the first object in the first frame is the same object as the second object in the second frame based on the determined first difference is determined by
based on the determined first difference, assigning a probability value to the second object in the second frame defining a likelihood of the first object in the first frame being the same object as the second object in the second frame.

19. The method of claim 16, wherein determining the first difference is determined by determining a difference between the size of the first object in the first frame and the size of the second object in the second frame.

20. The method of claim 16, wherein determining the first difference is determined by determining a distance between the position of the first object in the first frame and the position of the second object in the second frame.
